(19) United States
(12) Patent Application Publication
(10) Pub. No.: US 2022/0236019 A1
(43) Pub. Date: Jul. 28, 2022

(54) FLEXIBLE THERMAL CONNECTION STRUCTURE

(71) Applicant: DTEN, Inc., San Jose, CA (US)

(72) Inventors: Wei Liu, San Jose, CA (US); Jin Guo, San Jose, CA (US); Rui Xu, San Jose, CA (US)

(21) Appl. No.: 17/572,989

(22) Filed: Jan. 11, 2022

Related U.S. Application Data
(60) Provisional application No. 63/140,438, filed on Jan. 22, 2021.

(51) Int. Cl. F28F 1/12; F28F 9/00; F28F 13/00

(52) U.S. Cl. CPC F28F 1/12; F28F 9/001; F28F 2255/02; F28F 2013/001; F28F 2210/10; F28F 13/003

(57) ABSTRACT

A flexible temperature control system absorbs and dissipates heat includes a flexible member having a thermal conductor wound with a substantially constant spacing separation and a uniform pitch that encloses a cooling passage that extends therethrough. The thermal conductor has a plurality of side openings. An upper case and a lower case connect the flexible member and include a heat dissipating layer formed of aromatic crystal of carbon atoms linked together in a hexagonal lattice. The cooling passage encloses a foam layer that includes void mediums that increase the thermal conductivity between an upper interfacing element distant from a lower interfacing element.

### BACKGROUND OF THE DISCLOSURE

### 1. Priority Claim

This application claims the benefit of priority to U.S. Provisional Application No. 63/140,438 filed Jan. 22, 2021, titled “Elastic Thermal Connection Structure,” and is related to U.S. application Ser. No. 17/______ filed Jan. 11, 2022, filed under attorney docket number 49809-20008B, titled “Elastic Thermal Connection Structure”, and U.S. application Ser. No. 17/______ filed Jan. 11, 2022, filed under attorney docket number 49809-20008C, titled “Active Thermal Dissipating System,” all of which are herein incorporated by reference in their entirety.

### 2. Technical Field

This disclosure relates to heat dissipation and in particular to flexible temperature management systems for electronic circuits.

### 3. Related Art

Thermal induced failures are becoming increasingly common in electronic devices. As chips and circuits become smaller and denser, the heat they generate has become greater. Heat reduces chip and circuit reliability and performance.

To overcome the likelihood of thermal failures, passive thermal solutions transfer the heat onto passive surfaces where it is dissipated in close proximity to chips and circuits. Passive solutions are often ineffective as heat dissipation often occurs in a limited area near the components and circuits. To address this issue, some passive solutions increase the number of parts to increase convection. Even with this improvement, the passive solutions remain largely ineffective because the heat remains concentrated and continues to cause failures.

### BRIEF DESCRIPTION OF THE DRAWINGS

The disclosure can be better understood with reference to the following drawings and description. The components in the figures are not necessarily to scale, emphasis instead being placed upon illustrating the principles of the invention. Moreover, in the figures, like referenced numerals designate corresponding parts throughout the different views.

FIG. 1 is a partial perspective view and a top schematic view of an exemplary square-like flexible member.

FIG. 2 is a partial perspective view of two exemplary obround-like flexible members and a cross-sectional top view of one of them.

FIG. 3 is a partial perspective view and a top schematic view of an exemplary triangle-like flexible member.

FIG. 4 is a partial perspective view and a top schematic view an exemplary serpentine-like flexible member.

FIG. 5 is a partial perspective view and a plurality a top schematic view of an exemplary frusto-conical-like flexible member.

FIG. 6 is a partial perspective view and a top schematic view of an exemplary volute-like flexible member.

FIG. 7 is a flexible temperature control system.

FIG. 8 is a cross-sectional view of the flexible temperature control system of FIG. 1.

FIG. 9 is another flexible temperature control system.

FIG. 10 is a side perspective view of interfacing elements of the flexible temperature control system.

### DETAILED DESCRIPTION

A flexible temperature control system absorbs and dissipates heat generated by electrical components, circuits, and integrated circuits (referred to as chips). The flexible temperature control system prevents overheating at various temperatures and at various rates. By a portion of the system's close proximity to heat generating sources and another portion's separation from it, the systems provides axial and radial cooling paths away from heat generating sources. By minimizing the thermal contact resistance between the flexible member, a lower interfacing member, and the heat generating sources, the flexible temperature control system controls the temperature at the interface between the heat generating surface and flexible temperature control system (Tᵢₙₜ). By optimizing the gap spacing between the flexible elements and utilizing multiple flexible shapes in some systems, foam layers in other systems, cooling fans in others systems, and combinations in other systems, the flexible temperature control system sustains isothermal operating ranges to address different thermal and vibration conditions that adversely affect different chip environments.

Using a flexible element, the flexible temperature control systems exert and absorb force or torque and convey heat away from heat generating sources at the same time providing thermal diffusivity and vibration compensation for electronic devices. Mechanical forces are dampened and mechanical energy is stored in the flexible member as it is bent, twisted, stretched, and/or compressed. The system's thermal diffusivity varies with the flexible member in some systems, the density and porosity the medium enclosed in the central cooling passage and peripheral cooling passage in some systems (that both extend in parallel along the entire longitudinal length of the flexible member) and the thermal conductivity of the heat dissipating layer encloses some or all of the flexible temperature control systems.

The flexible member comprises many configurations including square-like members, obround-like members, triangular-like members, serpentinine-like members, and frustoconical-like members. Each are material to providing different levels of thermal diffusivity and mechanical dampening that are crucial to the operation of the respective systems in which they are a part of making them not a matter of design choice. Instead, they are critical to the various chips operating conditions.

Square and obround-like flexible members used in some systems are made of a round or rectangular homogenous or heterogenous core wire and/or thermal conductor with varying or substantially constant hollow and/or solid diameters/cross-sections. The wire and/or thermal conductor is wound with a substantially constant spacing separation that is measured along latitudinal flexible member's axis with a substantially uniform pitch. Pitch is the distance from the center of one element to the center of the adjacent element of the flexible member. It is sometime confused the gap or spacing between elements that comprise the flexible member.

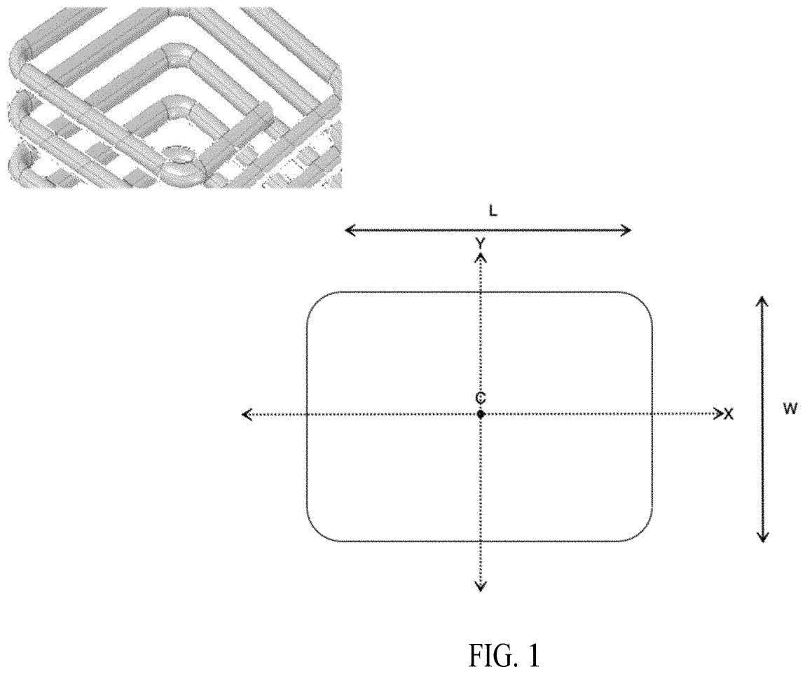

A profile of a square-like flexible member is shown in cross-section in FIG. 1. The length is L and the center of the square-like spring is coincident with the center of the corresponding curved-ended sides and midpoint of the corresponding sides formed by a round or a rectangular homogenous or heterogenous core wire and/or thermal conductor with varying or substantially constant coil hollow and/or solid diameters/cross-sections. The square-like member has a substantially constant gap spacing in some systems when not under compression or torsion. The flexible member's profile shows the symmetry about each of the quadrants of axes on the plane with the center coinciding with the geometric center. The square-like flexible member has a substantially constant gap spacing between elements in some systems when not under compression or torsion.

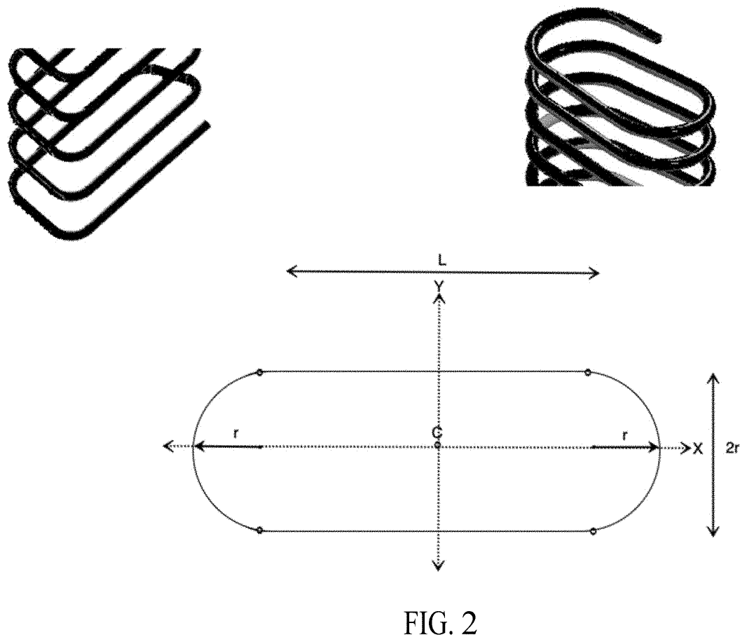

The obround-like flexible member shown in cross-section in FIG. 2 also has a length of L where the center of the circular arcs on either sides are coincident with the midpoint of the corresponding sides formed by a round or a rectangular homogenous or heterogenous core wire and/or thermal conductor with varying or substantially constant coil hollow and/or solid diameters/cross-sections. As seen, the profile shows symmetries about each of the quadrants of the coordinate axes within the plane of the origin coinciding with the geometric center of the obround-like member. Like the square-like flexible member, the mechanical and thermal properties of this flexible member can be derived by a quarter measurement of a portion of the coil or thermal elements multiplied by four. In other words, the mechanical and convection properties of these obround-like and square-like systems can evenly or substantially equally distribute the mechanical energy and heat through mechanical dampening and convection properties across each of four coordinate quadrants providing a granular mechanical and thermal dissipation by at least a factor of four.

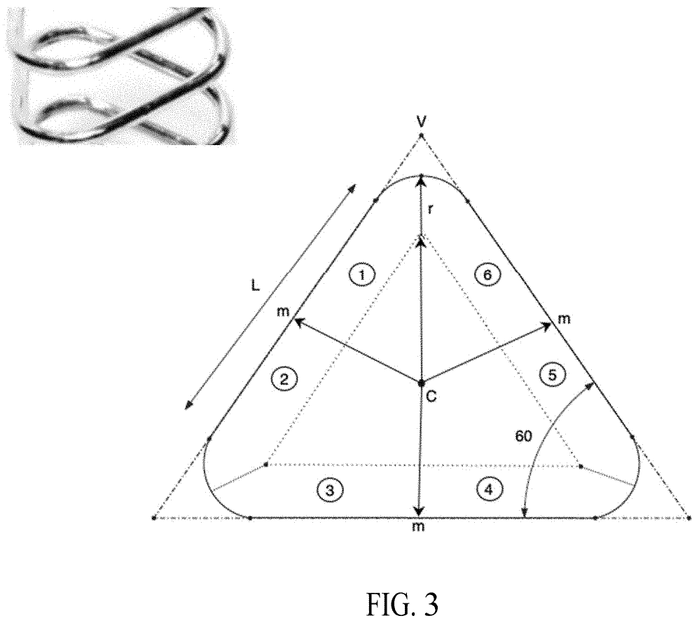

Triangular-like flexible members are made of a round or a rectangular homogenous or heterogenous core wire and/or thermal conductor with varying or substantially constant coil hollow and/or solid diameters/cross-sections and have a substantially constant gap spacing in some systems when not under compression or torsion. The wire and/or thermal conductor is wound with a substantially constant separation that is measured along latitudinal member's axis with a substantially uniform pitch. A profile of an equilateral triangular-like flexible member is shown in FIG. 3. The length of the straight side of the triangle is “L” and “V” is its vertex. “C” is the centroid of the triangle; “r” is the radius of the curved part of the triangle; and “m” is the midpoint of the respective sides. As shown, the equilateral triangular-like flexible member can be divided into six substantially equal portions allowing it to distribute mechanical and convection properties across six segmented portions evenly or substantially equally providing a granular dissipation to portions of heat generating components by a factor of six.

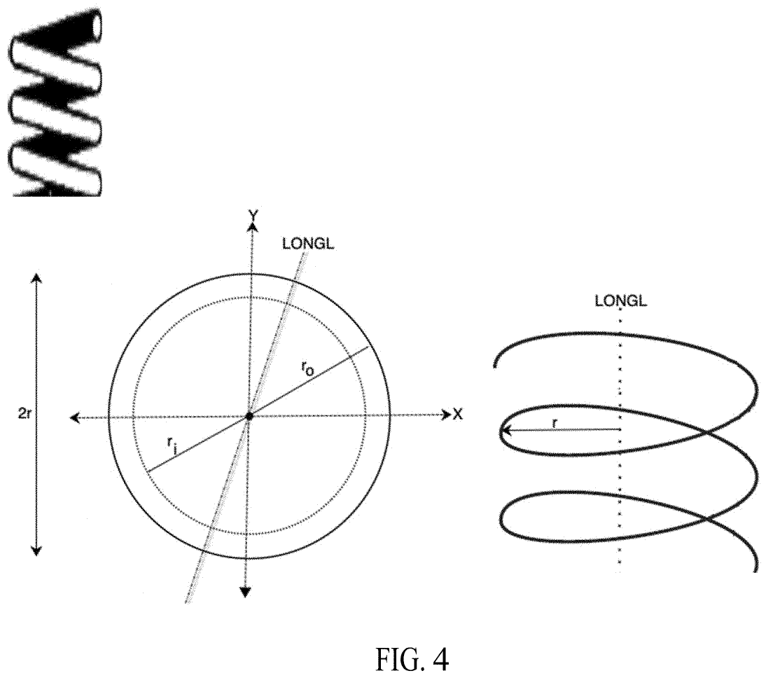

Torrid-like flexible member or serpentine-like members are made of a round or rectangular homogenous or heterogenous core wire and/or thermal conductor with varying or substantially constant coil hollow and/or solid diameters/cross-sections as shown in FIG. 4. The core wire and/or thermal conductor form a substantially constant gap spacing between elements in some systems when not under compression or torsion. The closed loop of wire and/or thermal conductor orbits around the longitudinal axis (shown as via the dashed line segment) while undergoing translation. In some systems, the orbit and translation are substantially constant. The mechanical and convection properties of these systems evenly or substantially equally distribute the mechanical and convection properties across an annulus portion of a chip across four coordinate quadrants.

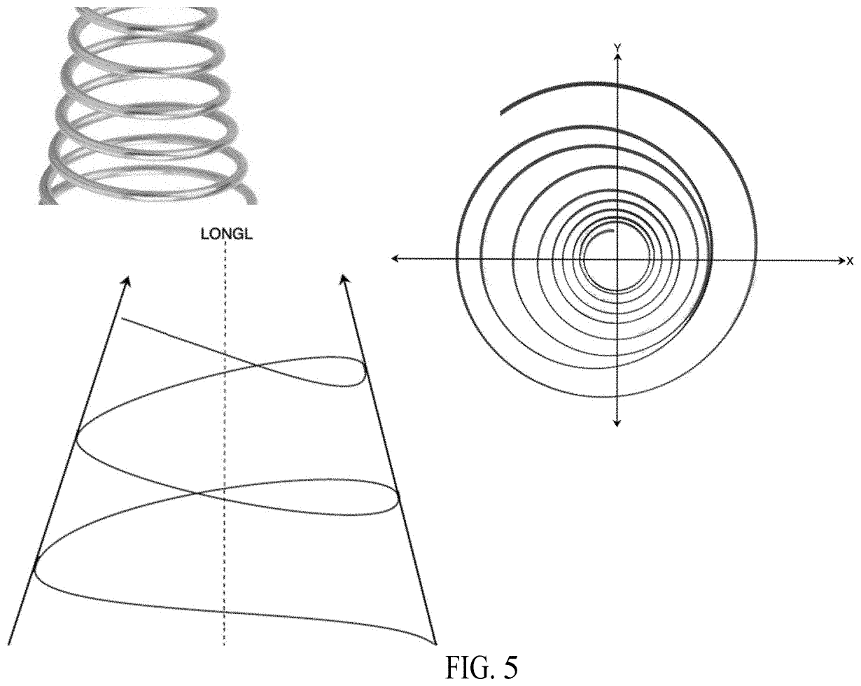

A frusto-conical-like flexible member comprises a surface of a thermal conductor generated by a moving straight line in which one point is fixed and touches a fixed curve as shown in FIG. 5. The conical apex plane or truncation plane is located substantially near a center in some systems, and off-center in other systems. The location of the truncation plane varies with the circuit and device geometries that the flexible temperature control system cools and provides a variable mechanical and thermal dissipation due to the variable radius of the ring-like or torrid-like members that get smaller as the frusto-conical-like flexible member extends from the base of a heat generating source to the heat dissipating surface. Frusto-conical-like flexible members are crucial to chips and devices that have large heat generating sources and limited cooling planes relative to the heat generating planes.

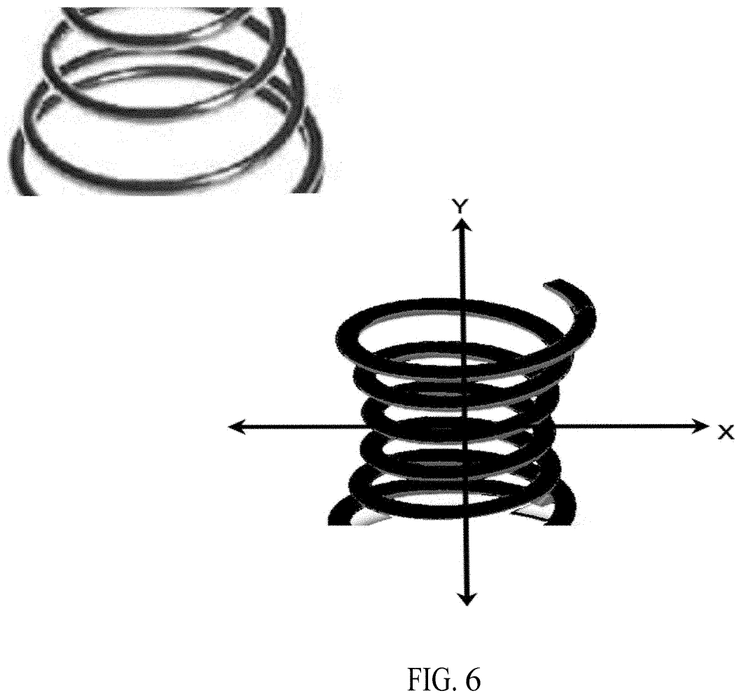

A volute-like flexible member is made of a round or rectangular homogenous or heterogenous core wire and/or thermal conductor with varying or substantially constant coil hollow and/or solid diameters/cross-sections. The volute-like flexible member shown in FIG. 6 has a linearly changing diameter, with the ends being substantially equal and being wider than the center. The volute-like flexible member comprises two “V” like shapes joined at a vertex (e.g., “><”) to form a distorted cylinder having wider diameters at the ends than at its center. The member forms symmetric interfacing contact planes or contact planes at the chips and/or heat dissipating layers. The volute-like member of FIG. 6 has a linearly varying pitch and higher mechanical damping due to the flexible member's structure and materials. While each of the flexible-members described herein will stop periodic motion and dampen vibrations without a mechanical damper, the damping effect of the volute-like member is greater than some flexible members due to the dynamic lag induced by the flexible member's configuration and materials that form them. The volute-like flexible member dampens the longitudinal waves that propagate through them. The dynamic lag is a phenomenon in which a physical property lags behind the changes that in effect cause it, which is crucial to some systems.

Using combinations heat dissipating layers and flexible members, the flexible temperature control systems dampen mechanical vibrations and remediate the heat generated by electronic devices. Some flexible members enclose or are encased by a light, porous, semi-grid physical material (e.g., foam). When electrical insulating and thermal conducting medium or mediums is/are injected within the foam's closed cells and/or voids (referred to as the void medium or filler) or are part of the foam itself and/or are coupled to a heat dissipating layer, convection and/or cooling rates increases systems. Some flexible temperature control systems also or alternatively circulate or draw in air at a constant or variable rates as described in the disclosures incorporated by reference.

Alternate flexible control systems include systems processes, and elements described in U.S. Provisional Application No. 63/140,438 filed Jan. 22, 2021, titled “Elastic Thermal Connection Structure,” and U.S. application Ser. No. 17/______ filed Jan. 11, 2022, filed under attorney docket number 49809-20008B, titled “Elastic Thermal Connection Structure”, and U.S. application Ser. No. 17/______ filed Jan. 11, 2022, filed under attorney docket number 49809-20008C, titled “Active Thermal Dissipating System”, which are all herein incorporated by reference. Alternate flexible temperature control systems include any combinations of structure and functions described or shown in these disclosures.

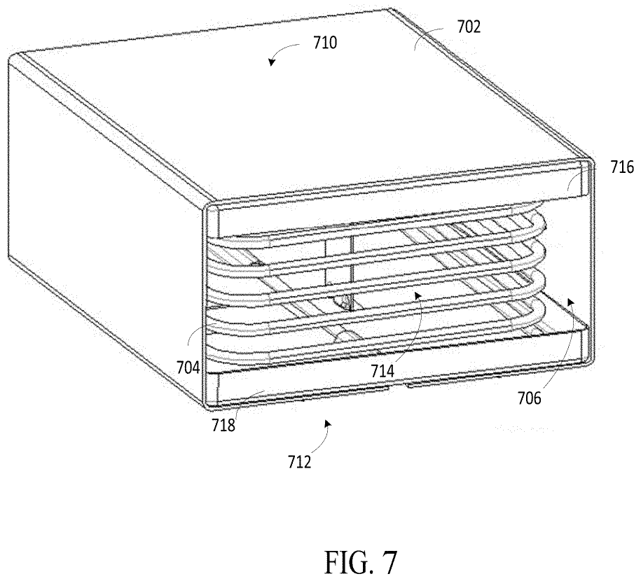

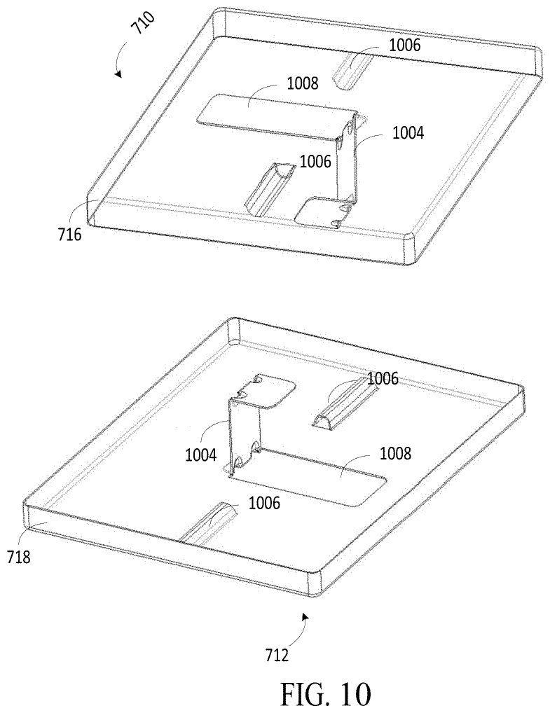

As shown in FIG. 7, an open sided flexible temperature control system include an outer heat dissipating layer or surface (referred to as a layer) 702 and an inner heat absorbing layer or surface facing opposite the outer heat dissipating layer (upper and side inner portions). A flexible member 704 is disposed therebetween the upper, lower, and side portions of the inner heat absorbing layer. The flexible member 704 couples an upper and lower interfacing element 710 and 712 (also shown in FIG. 10), with it upper and lower portion partially enclosed by an upper and lower case 716 and 718, respectively. The flexible member 704 has openings created by the gaps that separate the elastic elements that form the flexible member 704. The upper and lower case 716 and 718 comprise or include a heat dissipating layer 702 that also enclose other portions of the flexible thermal temperature control system. A peripheral cooling passage 706 comprising the region outside of a cooling passage 714 extends between the sides and upper and lower interfacing element 710 and 712 and an inner boundary formed by their side edges. A central cooling passage 714 meandering through the flexible member 704 includes an inlet and outlet terminating at a portion of the heat dissipating layers. In alternate systems, the outlet couples systems that circulate forced air like one or more cooling fans. In other systems, the central cooling passage 714 and peripheral cooling passage 706 comprises or are filled with a foam layer and the heat dissipating layer comprises one or more or any combination of heat dissipating layers as described herein and in the disclosures incorporated by reference.

The cooling passage 714 of FIG. 7 facilitates heat convection generated by heating components (e.g., chips) that is absorbed by the flexible member 704, cooling passage 714, and heat dissipating layer 702 remote from the heating components and lower interfacing element 710 that couples them. In some systems, the heat dissipating layer 702 (and upper and lower case 716 and 718 in some systems, fully enclosing the flexible temperature control system in alternate systems) comprise a one-atom-thick aromatic (e.g., a planar unsaturated ring of atoms) crystal having high thermal conductivities. When multiple layers are used, each layer may comprise carbon atoms linked together in a hexagonal lattice. The links are covalent bonds separated by only about 0.142 nanometers. The atoms may be linked to sp2 hybridized bonds, in a single layer of atoms, two dimensionally. Each two dimensional, one atom thick layer of sp2 bonded carbon items is separated by about 0.335 nm and have a thermal conductivity of at least 2000 W m⁻¹ K⁻¹ at ambient temperature when suspended.

Q=−κΔT (1.0)

where
Q=heat flux per unit area
κ=thermal conductivity
ΔT=temperature
The negative sign in equation 1.0 shows that the heat flow is from a high temperature heat generating sources to a lower temperature heat dissipating layer. The relationship between thermal conductivity and specific heat can be approximated (˜) by equation 1.2, where “v” is the average phonon group velocity and “λ” is the average phonon free path.

κ˜ΣC*vλ (1.2)

When attaching particles to the hexagonal lattice or wrapping nanoparticles (attaching nanoparticles or wrapping nanoparticles to it) to it improves thermal properties. For example, adding less than a thirty percent portion to the foam that comprises or fills the central cooling passage 714 and peripheral cooling passage 706 increases thermal conductivity by at least five percent.

In FIG. 7, the flexible member 704 is located between the upper and lower interfacing element 710 and 712. To improve thermal conductivity between the heat generating surfaces of the chips and the flexible temperature control system's interface temperature (Tint), the lower interfacing element 712 is thinner than the upper interfacing element 710, which reduces the relative thermal resistance between the lower interfacing element 712 and the heat generating sources and increases heat absorption. The square-like flexible member of FIG. 7 comprise a compression and tension member made of a round or rectangular homogenous or heterogenous core wire and/or thermal conductor with varying or substantially constant hollow and/or solid diameters/cross-sections. The wire or thermal conductor is wound with a substantially constant gap separation that is measured along the flexible member's latitudinal axis with a substantially uniform pitch when not under compression and tension. In some systems, the hollow core wire and/or thermal conductors 704 referenced in this disclosure may comprise materials having high thermal conductivity such diamond having a thermal conductivity of about 2000 W m⁻¹ K⁻¹ and/or materials having high thermal conductivity and high elasticities such as amorphous carbon having a thermal conductivity of about 0.01 W m⁻¹ K⁻¹, supported graphene filler having a thermal conductivity of at least bout 600 W m⁻¹ K⁻¹, and other filler materials including those described herein, incorporated by reference, and/or any combinations thereof. Such materials are crucial to systems that require low electrical conductivity such as diamond (to prevent chip shorting) and systems that require high thermal conductivity and elasticity to absorb vibrations (e.g., such as electronics in vehicles) that may use graphene. The choice of such materials that are crucial to system's operations that require a high thermal diffusity diffusivity, mechanical diffusivity, and/or electrical isolation.

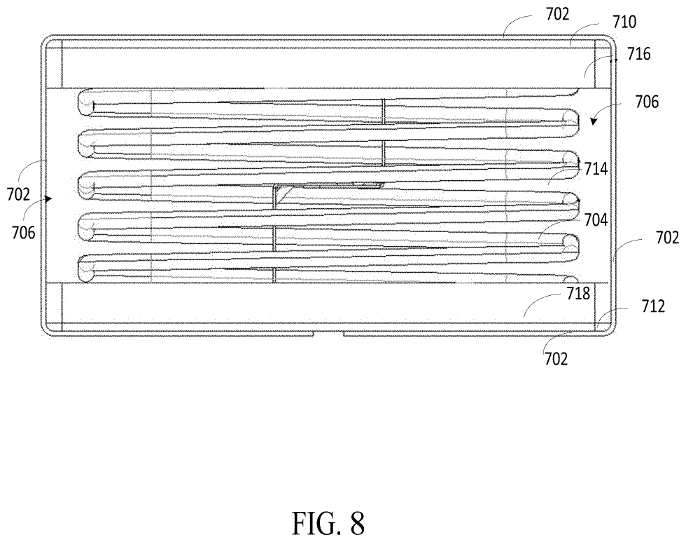

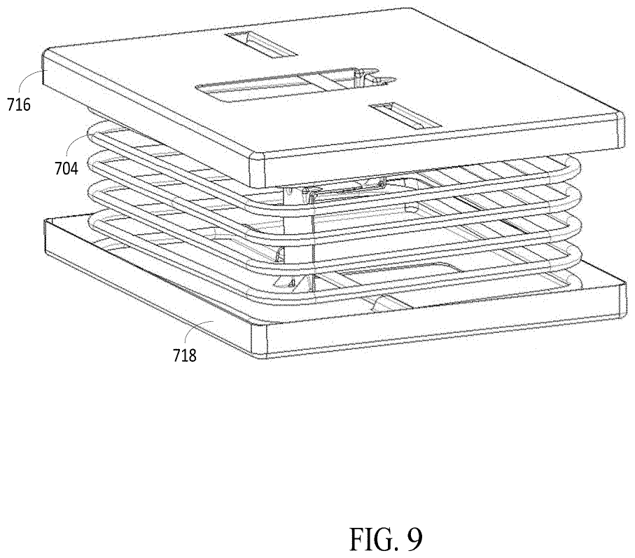

In FIGS. 7 and 8, the outer heat dissipating layer 702 comprising the upper heat dissipating layer remote from the heat generating sources or chips has a larger surface area than the flexible member 704 and the cooling passage 714 and peripheral cooling passage 706. The flexible member 704 includes its recessed upper portion and its recessed lower portion recessed within and in physical contact with the upper and lower interfacing element 710 and 712, respectively, within the upper and lower cases, 716 and 718, respectively. In FIG. 9 the side potions of the flexible temperature control system are exposed to receive a cooling medium and/or dissipate heat. The cooling medium may include forced air propelled by a cooling fan or coolant propelled through coolant tubes by a pump. In other systems, the sides of the flexible temperature control system are enclosed by the heat dissipating layer 702 and in some systems the cooling passage 714 and peripheral cooling passage 706 are filled with foam layers, and in some systems the foam layers include void mediums. As disclosed in the disclosures incorporated by reference, some void mediums are electrical conductors and are electrically tuned, some have high thermal conductivity and elasticity, some are good insulators, etc. all of which are crucial to the chips operation and thus not a matter of design choice.

In FIG. 10, the upper and lower interfacing element 710 and 712 include cutout portions 1002 adjacent compression limiters 1004. The “L” shaped compression limiters 1004 passes through the cooling passage 714 of flexible member 704 and are longitudinally aligned to regulate the compression force that biases the upper and lower interfacing element 710 and 712 and thus, are substantially centrally located within upper and lower case 716 and 718. Locking protuberances 1006 align the flexible member 704 that comprise square-like members in some systems, obround-like members in other systems, triangular-like members in other systems, serpentinine-like members in other systems, and/or frustoconical-like members in other systems.

In operation, a heating source such as a semiconductor device (e.g., a chip) generates heat. Heat generated by the heating source is transferred through the lower interfacing element 712 to the flexible member 702. Heat exchange occurs through the central cooling passage 714 meandering through the flexible member 704 and peripheral cooling passage 706. The lower interfacing element 714 and flexible member 702 is cooled by a void medium within and around the flexible member 702, air in some systems and the fully enclosed heat dissipating surfaces 702 that partially or fully surround and enclose the flexible member 702. In some systems, the flexible member 702 and heat dissipating layers 702 are forcibly cooled by a cooling fan (such as those disclosed herein) increasing convection and the heat flow rate. In FIGS. 7-10, the cutout portions 1008 passing through the upper and lower interfacing element 710 and 712 reduces the thermal stress generated when heat is generated by the heating source by providing a free-flow path.

Many other alternatives are possible. For example, the locking protuberances 1006 and the compression limiter 1004 may be unitary part of the upper and lower interfacing element 710 and 712 or separately formed and attached to one or both upper and lower interfacing element 710 and/or 712 or to a side surface of one or both upper and lower interfacing element 710 and 712. In some alternate systems, the protuberances' 1006 Quonset-shape and open recesses that reduces thermal resistance may comprise a flange or locking rib in the upper and lower interfacing element 710 and 712. In this system, the locking protuberance 1006 does not extend into the central cooling passage 714. Further, in some systems, the flexible member 704 comprises obround members in some systems, triangular members in other systems, serpentinine members in other systems, and/or frustoconical members in other systems.

When functions, steps, etc. are said to be “responsive to” or occur “in response to” another function or step, etc., the functions or steps necessarily occur as a result of another function or step, etc. It is not sufficient that a function or act merely follow or occur subsequent to another. The term “coupled” is intended to broadly encompass direct and indirect coupling. Thus, first and second parts are said to be coupled when they directly contact one another, as well as when the first part couples an intermediate part which couples either directly or via one or more additional intermediate parts. The term “position” is intended to broadly encompass a range of positions. The term “lock” is intended to broadly encompass a mechanical engagement that limits motions of the parts through a fixed engagement. The term “substantially” or “about” is intended to broadly encompass a range that is largely (ninety five percent or more), but not always wholly, that which is specified. It encompasses all but an insignificant amount such as within five percent and includes its limits in some systems. The term “near” means within a short distance (e.g., conventionally measured in centimeters) or interval in space or time.

While each of the systems and methods shown and described herein operate automatically and operate independently, they also may be encompassed within other systems and methods such as the teleconferencing system. A teleconferencing system uses audio, video, and/or computer equipment linked through a communication system to enable geographically separate individuals usually to participate in meeting or discussions. The meeting include video images that are transmitted to various geographically separate locations. Typically, the images comprise digital images transmitted over a wider area network or the Internet and include input and displays from application programs in real time.

Alternate flexible temperature control systems may include any combinations of structure and functions described or shown in one or more of the FIGS. These flexible temperature control systems and methods are formed from any combination of structures and functions described. Further when elements or components are described as “like” those elements and member encompass the shapes or exact shapes as well. The structures and functions may process additional or different input. Further, the systems illustratively disclosed herein may be practiced in the absence of any element (or member) not specifically disclosed herein.

The flexible temperature control systems compensate for the miniaturization of electronic circuits and increasing circuit densities. Using systems that absorb and dissipate heat passively and forcible air convection in alternate systems, the flexible temperature control system maintains optimum isothermal operating ranges and consistent heat flux removal. By minimizing the thermal contact resistance between the flexible member 704, upper and lower interfacing element 710 and 712, and the heat generating sources, the flexible temperature control system controls the temperature at the interface between the heat generating surface and flexible temperature control system. By optimizing the spacing between the flexible elements and utilizing multiple flexible shapes in some systems, foam layers in other systems, cooling fans in others systems, and combinations in other systems, the flexible temperature control system sustains isothermal operating temperature ranges. The system requires a lower number of parts providing both economic benefits and safety enhancements not found in conventional systems

Using a flexible element, the flexible temperature control systems exert force or torque and convey heat away from heat generating sources at a constant or varied rate as described by the flexible members 704 and void medium that is incorporated by reference. Mechanical energy is stored in the flexible member 705 as it is bent, twisted, stretched, and/or compressed. The flexible member's 702 thermal conduction band provides high conductivity.

Other systems, methods, features and advantages will be, or will become, apparent to one with skill in the art upon examination of the figures and detailed description. It is intended that all such additional systems, methods, features and advantages be included within this description, be within the scope of the disclosure, and be protected by the following claims.

What is claimed is:

1. A flexible temperature control system that absorbs and dissipates heat, comprising;
a flexible member comprising a thermal conductor wound with a substantially constant spacing separation and a uniform pitch enclosing a cooling passage that extends therethrough and a plurality of side openings; and
an upper case and a lower case coupled to the flexible member comprising a heat dissipating layer comprising aromatic crystal of carbon atoms linked together in a hexagonal lattice;
said cooling passage enclosing a foam layer that includes void mediums that increase the thermal conductivity between an upper interfacing element distant from a lower interfacing element.

2. The flexible temperature control system of claim 1, where the flexible member comprises a square flexible member having a profile symmetric about a plurality of quadrants of a plurality of axes on a plane with an origin coinciding with a geometric center of the square flexible member.

3. The flexible temperature control system of claim 2, where a core of the flexible member comprises graphene filler having a thermal conductivity of at least bout 600 W m⁻¹ K⁻¹.

4. The flexible temperature control system of claim 1, where the flexible member comprises a obround flexible member comprising circular arcs and a plurality of corresponding sides positioned so that the center of the circular arcs on either of the plurality of corresponding sides are coincident with a common midpoint of the plurality of corresponding sides.

5. The flexible temperature control system of claim 1, where the flexible member comprises a triangle flexible member comprising an equilateral triangular flexible member positioned so that the triangle flexible member divided into six substantially equal portions that distribute mechanical and convection properties across the six portions substantially equally.

6. The flexible temperature control system of claim 1, where the flexible member comprises a torrid flexible member comprising closed loop of a thermal conductor orbiting around a longitudinal axis while undergoing a translation.

7. The flexible temperature control system of claim 1, where the flexible member comprises a frusto-conical member having a surface of a thermal conductor generated by a moving straight line having one point fixed coupling a fixed curve and a truncation plane positioned substantially near a center of the frusto-conical member.

8. The flexible temperature control system of claim 1, where the flexible member has a linearly changing diameter, with a plurality of ends substantially equal and wider than a center; the flexible member comprising a plurality of “V” shapes joined at a vertex.

9. The flexible temperature control system of claim 7 where the flexible member forms a plurality of symmetric interfacing contact planes with a first contact plane coupled to an electronic chip and a second contact plane coupled the heat dissipating layers.

10. The flexible temperature control system of claim 7, where a core of the flexible member has a high elasticity and a thermal conductivity of about 600 W m⁻¹ K⁻¹.

11. The flexible temperature control system of claim 7, further comprising a plurality of compression limiters that pass thorough the cooling passage to regulate a compression force that bias the flexible member.

12. The flexible temperature control system of claim 11, further comprising a plurality of locking protuberances that align the flexible member.

13. The flexible temperature control system of claim 11, where the plurality of locking protuberances comprise a unitary part of an upper interfacing element and a lower interfacing element, respectively.

14. The flexible temperature control system of claim 13, further comprising a plurality of cutout portions passing through the upper interfacing element and the lower interfacing element, respectively, that reduce a thermal stress generated by a heat generating source.

15. The flexible temperature control system of claim 14, where the plurality of locking protuberances extent within the cooling passage.

16. The flexible temperature control system of claim 1, further comprising a peripheral cooling passage that extends along an entire longitudinal length of the flexible member.

17. The flexible temperature control system of claim 16, where the peripheral cooling passage is enclosed by the heat dissipating layer.

18. The flexible temperature control system of claim 16, further comprising a cooling fan that directs air to the heat dissipating layer.

19. A flexible temperature control system that absorbs and dissipates heat, comprising;
a flexible member comprising a thermal conductor wound with a substantially constant spacing separation and a uniform pitch enclosing a cooling passage that extends entirely therethrough and is positioned adjacent to and parallel to a peripheral cooling passage; and
an upper case and a lower case coupled to the flexible member comprising a heat dissipating layer comprising aromatic crystal of carbon atoms linked together in a hexagonal lattice;
said cooling passage enclosing a foam layer that includes void mediums that increase the thermal conductivity between an upper interfacing element distant from a lower interfacing element.

20. A flexible temperature control system that absorbs and dissipates heat, comprising;
a flexible member comprising a thermal conductor wound with a substantially constant spacing separation and a uniform pitch enclosing a cooling passage that extends entirely therethrough and is positioned adjacent to and parallel to a peripheral cooling passage; and
an upper case and a lower case coupled to the flexible member comprising a heat dissipating layer comprising aromatic crystal of carbon atoms linked together in a hexagonal lattice;
said cooling passage enclosing a foam layer that includes void mediums that increase the thermal conductivity between an upper interfacing element distant from a lower interfacing element;
said flexible member comprises a square flexible member having a profile symmetric about a plurality of quadrants of a plurality of axes on a plane with an origin coinciding with a geometric center of the square flexible member; and
said flexible member comprises graphene filler having a thermal conductivity of at least bout 600 W m⁻¹ K⁻¹.
